(19) United States
(12) Patent Application Publication
(10) Pub. No.: US 2025/0370356 A1
(43) Pub. Date: Dec. 4, 2025

(54) OPTICAL SYSTEM AND PROJECTION EXPOSURE SYSTEM

(71) Applicant: Carl Zeiss SMT GmbH, Oberkochen (DE)

(72) Inventors: Semih OEZTUERK, Schondorf (DE); Guido LIMBACH, Aalen (DE)

(21) Appl. No.: 19/303,806

(22) Filed: Aug. 19, 2025

Related U.S. Application Data
(63) Continuation of application No. PCT/EP2024/053551, filed on Feb. 13, 2024.

(30) Foreign Application Priority Data
Mar. 1, 2023 (DE) 10 2023 201 858.6

(51) Int. Cl. G03F 7/00; F16C 17/10; G02B 7/182

(52) U.S. Cl. CPC G03F 7/70825; F16C 17/10; G02B 7/182; G03F 7/70991

(57) ABSTRACT

An optical system for a projection exposure apparatus, comprises an optical element, a load-bearing structure for carrying the optical element, and an interface coupling the optical element and the load-bearing structure. The interface comprises a first Hirth serration assigned to the optical element. The interface comprises a second Hirth serration assigned to the load-bearing structure. The first Hirth serration and the second Hirth serration mesh in order to define a pose of the optical element in a reference coordinate system.

### CROSS-REFERENCE TO RELATED APPLICATIONS

The present application is a continuation of, and claims benefit under 35 USC 120 to, international application No. PCT/EP2024/053551, filed Feb. 13, 2024, which claims benefit under 35 USC 119 of German Application No. 10 2023 201 858.6, filed Mar. 1, 2023. The entire disclosure of each of these applications is incorporated by reference herein.

### FIELD

The present disclosure relates to an optical system for a projection exposure apparatus and to a projection exposure apparatus having such an optical system.

### BACKGROUND

Microlithography is used to produce microstructured component parts, for example integrated circuits. The microlithography process is performed using a lithography apparatus that comprises an illumination system and a projection system. The image of a mask (reticle) illuminated via the illumination system is in this respect projected via the projection system onto a substrate, for example a silicon wafer, that has been coated with a light-sensitive layer (photoresist) and is arranged in the image plane of the projection system, in order to transfer the mask structure to the light-sensitive coating of the substrate.

Driven by a desire for ever smaller structures in the production of integrated circuits, EUV lithography apparatuses that use light at a wavelength ranging from 0.1 nm to 30 nm, such as 13.5 nm, are currently under development. In the case of such EUV lithography apparatuses, because of the high absorption of light at this wavelength by most materials, reflective optics units, i.e. mirrors, are typically used instead of-as previously—refractive optics units, i.e. lens elements.

In such projection systems, it may be desirable to remove and reinstall mirrors or replace them with other mirrors. It would be desirable to reproducibly reestablish a pose of the respective mirror during the installation of the same. Thus, it would be desirable to provide an interface that allows the pose of the mirror to be reestablished with great accuracy when the same mirror is installed.

### SUMMARY

The present disclosure seeks to provide an improved optical system for a projection exposure apparatus.

The present disclosure proposes an optical system for a projection exposure apparatus. The optical system comprises an optical element, a load-bearing structure for carrying the optical element and an interface, with the aid of which the optical element is coupled to the load-bearing structure, wherein the interface comprises a first Hirth serration, assigned to the optical element, and a second Hirth serration, assigned to the load-bearing structure, and wherein the first Hirth serration and the second Hirth serration mesh in order to define a pose of the optical element in a reference coordinate system.

As a result of the interface comprising the first Hirth serration and the second Hirth serration, it is possible to reproducibly align the optical element and the load-bearing structure to one another with little outlay such that the interface defines the pose of the optical element in the reference coordinate system.

The optical system can be a projection optics unit or a part of a projection optics unit of the projection exposure apparatus. However, the optical system may also be an illumination optics unit or part of an illumination optics unit of the projection exposure apparatus. However, the assumption made below is that the optical system is a projection optics unit or part of such a projection optics unit. Accordingly, the term “optical system” may be replaced by the term “projection optics unit”.

In the present case, an “optical system” may be understood to mean, in particular, a system that is suitable for handling or influencing light, especially illumination radiation in the projection exposure apparatus. In the present case, “handling” or “influencing” may be understood to mean, for example, a deflection and/or refraction of the light. For example, the optical element may reflect or deflect the light.

The optical element can be a mirror or can comprise a mirror. For example the optical element may be an EUV mirror or comprise an EUV mirror. The optical element can comprise a substrate, for example a glass ceramic block or a ceramic block, on which an optically effective surface, for example a mirror surface, is provided. However, the optical element may also be an optical waveguide or comprise an optical waveguide.

In the present case, the load-bearing structure may be a force frame of the optical system, for example. However, the load-bearing structure may also be any other component part, for example a housing, such as a housing of an interferometer. In the present case, the load-bearing structure “carrying” the optical element means that, for example, the load- bearing structure is configured to absorb a weight of the optical element. For example, the load-bearing structure holds the optical element in its pose, for example in a target pose of the optical element.

In the present case, the optical element being “coupled” to the load-bearing structure with the aid of the interface means that, for example, the interface connects the optical element to the load-bearing structure. For example, forces from the optical element are introduced into the load-bearing structure, or vice versa, via the interface. However, this is not mandatory. Information as regards the pose that the optical element should adopt in the reference coordinate system may be stored in the interface. This information may be stored in a geometry of the interface, for example in a serration geometry. When the optical element is removed and subsequently installed or replaced, the information leads to the optical element being placed back into its predetermined pose without any additional adjustment or alignment.

In the present case, a “Hirth serration” is understood to mean, in particular, an axially effective, plane-side serration. An interlocking connection is provided between the first Hirth serration and the second Hirth serration. Thus, the Hirth serrations mesh in interlocking fashion. An interlocking connection arises as a result of two connection partners, the two Hirth serrations in the present case, meshing with or engaging behind one another. In the present case, the first Hirth serration being “assigned” to the optical element may mean that, in particular, the first Hirth serration is attached to the optical element. However, this is not mandatory. The same applies to the second Hirth serration and the load-bearing structure.

Both the first Hirth serration and the second Hirth serration can comprise a plurality of teeth that are arranged in distributed fashion, such as uniformly, around a central axis or axis of symmetry of the interface. Starting from the axis of symmetry, the teeth of the Hirth serrations extend radially to the outside. The teeth of the first Hirth serration can mesh with the teeth of the second Hirth serration in interlocking fashion, or vice versa.

In principle, a Hirth serration enables a parallel connection of a plurality of pairs of surfaces as a surface contact. This results in great static overdetermination. The high degree of static overdetermination generally involves very high surface accuracies and tolerances when manufacturing the Hirth serrations. As soon as this is achieved, however, it is possible to obtain a further improvement in the overall accuracies by way of what is known as the elastic averaging of inaccuracies. A principle of “elastic averaging” describes a state in which two objects, the Hirth serrations in the present case, are connected to one another in a very overdetermined manner by way of many contact points. In this case, the manufacturing accuracy of machines used to manufacture Hirth serrations can be surpassed. Moreover, the stiffness of the interface and its load-bearing capacity multiplies with increasing degree of static overdetermination.

The reference coordinate system comprises a first spatial direction or x-direction, a second spatial direction or y-direction and a third spatial direction or z-direction. In this reference coordinate system, the optical element has six degrees of freedom, namely three translational degrees of freedom in the x-direction, the y-direction and the z-direction, and three rotational degrees of freedom about the x-direction, the y-direction and the z-direction. That is to say, a position and an orientation of the optical element can be determined or described with the aid of the six degrees of freedom. The axis of symmetry corresponds to the z-direction or extends parallel thereto. The first Hirth serration and the second Hirth serration mesh in order to define the pose of the optical element in all six degrees of freedom or else in only three degrees of freedom, for example.

The “position” of the optical element is understood to mean, in particular, its coordinates, or coordinates of a point of interest provided on the optical element, with respect to the x-direction, the y-direction and the z-direction. The “orientation” of the optical element is understood to mean, in particular, its tilt in relation to the three directions. That is to say, the optical element may be tilted about the x-direction, the y-direction and/or the z-direction.

This gives the six degrees of freedom for the position and/or orientation of the optical element. The “pose” of the optical element comprises both its position and its orientation. The term “pose” is accordingly replaceable by the wording “position and orientation”, and vice versa. In the present case, the first Hirth serration and the second Hirth serration meshing in order to “define” the pose of the optical element in the reference coordinate system is understood to mean that, in particular, the captured or calibrated pose of the optical element during a removal and reinstallation or during a replacement of the optical element is re-establishable reproducibly and with great accuracy with the aid of the two Hirth serrations. For example, the optical element is brought into its target pose during the reinstallation or replacement.

According to an embodiment, the optical system further comprises a first serration portion attached to the optical element and comprising the first Hirth serration, and a second serration portion attached to the load-bearing structure and comprising the second Hirth serration.

The first serration portion may have a cylindrical geometry. For example, the first serration portion is constructed rotationally symmetrically with respect to the axis of symmetry of the interface. For example, facing away from the first Hirth serration, the first serration portion has an end face oriented perpendicular to the axis of symmetry. Further, the first serration portion comprises an outer surface that extends rotationally symmetrically around the axis of symmetry. The same applies to the second serration portion.

According to an embodiment, the first serration portion and/or the second serration portion comprises fastening apertures serving to fasten the first serration portion and/or the second serration portion and guided through the first Hirth serration and/or through the second Hirth serration.

With the aid of the fastening apertures, it is possible to interlockingly connect the respective serration portion to further components or component parts, for example by way of screwing. For example, only the first serration portion comprises such fastening apertures. In addition to that or in an alternative, the second serration portion might also comprise such fastening apertures. In the case where the first serration portion comprises fastening apertures, these are guided through the first Hirth serration, in a manner parallel to the axis of symmetry through the first Hirth serration. Accordingly, in the case where the second serration portion likewise comprises fastening apertures, these are guided through the second Hirth serration in a manner parallel to the axis of symmetry. For example, the fastening apertures are guided directly through the teeth of the respective serration portion.

According to an embodiment, the first serration portion and/or the second serration portion comprises a central aperture, around which the first Hirth serration and/or the second Hirth serration extends.

For example, the respective Hirth serration extends around the entire respective aperture. However, this is not mandatory. The Hirth serrations may also extend around the axis of symmetry only in part. The respective Hirth serration is segmented in this case. The aperture extends along the axis of symmetry. The aperture may be constructed rotationally symmetrically with respect to the axis of symmetry. A centering element may be received in this aperture. For example, both the first serration portion and the second serration portion comprise such a central aperture. In this case, the first Hirth serration extends around the aperture in the first serration portion. In the case where the second serration portion likewise comprises such an aperture, the second Hirth serration extends around this aperture. In the present case, the respective Hirth serration “extending around” the aperture means that, in particular, the teeth of the respective Hirth serration are arranged with uniform distribution about the axis of symmetry of the interface. The Hirth serrations may extend around the respective aperture in ring-shaped or circular fashion.

According to an embodiment, the first Hirth serration and/or the second Hirth serration is subdivided into serration segments that are arranged in alternation with toothless segments of the first Hirth serration and/or the second Hirth serration.

In the present case, “toothless” or “tooth-free” segments are understood to mean segments of the respective serration portion that have no teeth. For example, a toothless segment is always arranged between two serration segments, and vice versa. For example, only the first Hirth serration or only the second Hirth serration might be subdivided into serration segments. Further, both the first Hirth serration and the second Hirth serration might also be subdivided into serration segments. Further, it is also possible that only the second Hirth serration is subdivided into serration segments. The number of serration segments and toothless segments is as desired. However, at least two serration segments and at least two toothless segments are optionally provided. The desire to provide toothless segments may be due to improved producibility of the respective Hirth serration.

According to an embodiment, the first serration portion and/or the second serration portion comprises a spring element that carries teeth of the first Hirth serration and/or of the second Hirth serration.

In this case, three degrees of freedom are decoupled, and three degrees of freedom are blocked. The spring element can be a leaf spring element and may therefore also be referred to as such. The teeth can extend out of the spring element. The teeth and the spring element may be formed in one piece, for example from one piece of material. In the present case, “in one piece” or “integrally” means that the spring element and the teeth form a joint component and are not assembled from different component parts. In the present case, “from one piece of material” means that the spring element and the teeth are manufactured from the same material throughout. For example, only the first serration portion comprises such a spring element that carries teeth of the first Hirth serration. In an alternative to that or in addition, the second serration portion may likewise comprise such a spring element that carries teeth of the second Hirth serration.

According to an embodiment, the spring element is oriented perpendicular to an axis of symmetry of the interface.

In the present case, “perpendicular” should be understood to mean an angle of 90°±10°, such as 90°±5°, for example 90°±3°, for example 90°±1°, for example exactly 90°. For example, the spring element spans a plane that is arranged perpendicular to the axis of symmetry of the interface.

According to an embodiment, the spring element has its lowest stiffness when viewed along the axis of symmetry.

The levels of tilting stiffness of this axis of symmetry likewise have low levels of stiffness. For example, the spring element prevents a transfer of force via the interface along the axis of symmetry. In this case, the transfer of force along the axis of symmetry is optionally not implemented via the interface itself but for example via contact surfaces at which the optical element rests indirectly or directly on the load-bearing structure. In this case, the respective Hirth serration adopts the positioning in the x-direction and in the y-direction and, as regards the rotational degree of freedom, about the z-direction. In very general terms, the “stiffness” describes the resistance of a body to an elastic deformation imposed thereon by an external load and conveys the relationship between the load on the body and its deformation. The stiffness is determined by the material of the body and its geometry. For example, the stiffness of the spring element may be varied or set by modifying a wall strength or wall thickness of the same.

According to an embodiment, the optical system further comprises a mirror bushing, assigned to the optical element and comprising the first serration portion, and a bushing block, assigned to the load-bearing structure and comprising the second serration portion.

The load-bearing structure may be embodied as a hexapod. The interface is provided between the mirror bushing and the bushing block. For example, the first Hirth serration may be attached directly to the mirror bushing. Accordingly, the second Hirth serration may be formed directly on the bushing block. However, the first serration portion may also be a component that is separate from the mirror bushing and for example screwed to the mirror bushing. Accordingly, the second serration portion may also be a component that is separate from the bushing block and for example interlockingly connected, more particularly screwed, to the bushing block.

According to an embodiment, the optical element comprises an optically effective surface and a back side facing away from the optically effective surface, wherein the mirror bushing is connected to the back side.

As mentioned previously, the optically effective surface can be a mirror surface. For example, the optically effective surface may be realized by a coating. Optionally, the back side has no defined optical properties.

According to an embodiment, the mirror bushing and the first serration portion are formed in one piece, especially from one piece of material, or in multiple pieces, and/or wherein the bushing block and the second serration portion are formed in one piece, especially from one piece of material, or in multiple pieces.

For example, the first serration portion is formed directly on the mirror bushing. In this case, the mirror bushing and the first serration portion are formed in one piece. Alternatively, the mirror bushing and the first serration portion may also be two mutually separate components that are detachably connected to each other. Correspondingly, the second Hirth serration may also be formed directly on the bushing block. In this case, the bushing block and the second serration portion are formed in one piece. Alternatively, the bushing block and the second serration portion may also be two mutually separate components that are detachably connected to each other. It is also possible that the mirror bushing and the first serration portion are formed in one piece, and the bushing block and the second serration portion are formed in multiple pieces. The same also applies the other way around.

According to an embodiment, the optical system further comprises three mirror bushings attached to the optical element, with each mirror bushing being assigned two degrees of freedom of the optical element.

For example, two degrees of freedom of the optical element are blocked at each mirror bushing. Consequently, the six degrees of freedom of the optical element arise from three mirror bushings.

According to an embodiment, the optical system further comprises three bipods that couple the optical element to the load-bearing structure with the aid of the bushing block, with each mirror bushing being assigned a bipod.

Provision is made either for three bipods or for one hexapod. For example, a bushing block is also assigned to each bipod. For example, this means that three bushing blocks are provided, with each mirror bushing being assigned one bushing block. Each bipod is assigned two degrees of freedom of the optical element.

According to an embodiment, the optical element comprises an optical waveguide and a fiber connector, which carries the optical waveguide, with the first Hirth serration being provided on the fiber connector.

In this case, the load-bearing structure may be an interferometer, such as a housing of the interferometer. With the aid of the interface, it is possible to position the optical waveguide on the load-bearing structure with great accuracy.

Furthermore, a projection exposure apparatus having such an optical system is proposed.

The optical system can be a projection optics unit of the projection exposure apparatus. However, the optical system may also be an illumination system. The projection exposure apparatus may be an EUV lithography apparatus. EUV stands for “extreme ultraviolet” and refers to a wavelength of the operating light of between 0.1 nm and 30 nm. The projection exposure apparatus may also be a DUV lithography apparatus. DUV stands for “deep ultraviolet” and refers to a wavelength of the operating light of between 30 nm and 250 nm.

“A” or “an” in the present context should not necessarily be regarded as a restriction to exactly one element. Instead, multiple elements, for example two, three or more, may also be provided. Any other numeral used here should also not be understood as a restriction to exactly the stated number of elements. Rather, numerical deviations upward and downward are possible, unless indicated otherwise.

The embodiments and features described for the optical system apply correspondingly to the proposed projection exposure apparatus, and vice versa.

Further possible implementations of the disclosure also encompass not explicitly mentioned combinations of features or embodiments that are described above or hereinafter with respect to the exemplary embodiments. A person skilled in the art will also add individual aspects as improvements or supplementations to the respective basic form of the disclosure.

Further configurations and aspects of the disclosure are the subject of the claims and of the exemplary embodiments of the disclosure that are described hereinafter.

### BRIEF DESCRIPTION OF THE DRAWINGS

The disclosure is explained in greater detail hereinafter on the basis of certain embodiments with reference to the appended figures.

FIG. 1 shows a schematic meridional section of a projection exposure apparatus for EUV projection lithography;

FIG. 2 shows a schematic view of one embodiment of an optical system for the projection exposure apparatus in accordance with FIG. 1;

FIG. 3 shows a schematic plan view of the optical system in accordance with FIG. 2;

FIG. 4 shows a schematic perspective view of one embodiment of an interface for the optical system in accordance with FIG. 2;

FIG. 5 shows a further schematic perspective view of the interface;

FIG. 6 shows a schematic sectional view of a further embodiment of an interface for the optical system in accordance with FIG. 2;

FIG. 7 shows a schematic sectional view of a further embodiment of an interface for the optical system in accordance with FIG. 2;

FIG. 8 shows a schematic plan view of a further embodiment of an interface for the optical system in accordance with FIG. 2;

FIG. 9 shows a schematic side view of a further embodiment of an interface for the optical system in accordance with FIG. 2; and

FIG. 10 shows a schematic sectional view of a further embodiment of an optical system for the projection exposure apparatus in accordance with FIG. 1.

### DETAILED DESCRIPTION

In the figures, identical or functionally identical elements have been provided with the same reference signs, unless indicated otherwise. Furthermore, it should be noted that the illustrations in the figures are not necessarily true to scale.

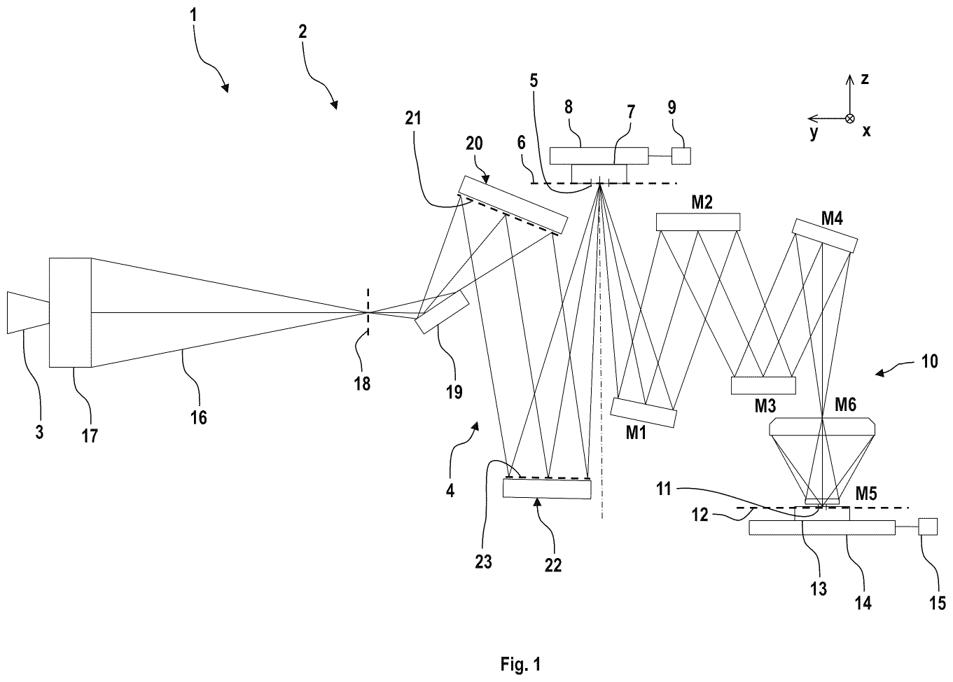

FIG. 1 shows one embodiment of a projection exposure apparatus 1 (lithography apparatus), for example an EUV lithography apparatus. In addition to a light source or radiation source 3, an embodiment of an illumination system 2 of the projection exposure apparatus 1 has an illumination optics unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 depicts, for explanation purposes, a Cartesian coordinate system with an x-direction x, a y-direction y, and a z-direction z. The x-direction x runs perpendicularly into the plane of the drawing. The y-direction y runs horizontally, and the z-direction z runs vertically. The scanning direction runs in the y-direction y in FIG. 1. The z-direction z runs perpendicularly to the object plane 6.

The projection exposure apparatus 1 comprises a projection optics unit 10. The projection optics unit 10 serves for imaging the object field 5 into an image field 11 in an image plane 12. The image plane 12 extends parallel to the object plane 6. In an alternative, an angle that differs from 0° is also possible between the object plane 6 and the image plane 12.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction y. The displacement, firstly, of the reticle 7 by way of the reticle displacement drive 9 and, secondly, of the wafer 13 by way of the wafer displacement drive 15 may be implemented so as to be synchronized with one another.

The light source 3 is an EUV radiation source. The light source 3 emits EUV radiation 16, which is also referred to below as used radiation, illumination radiation or illumination light. The used radiation 16 has for example a wavelength in the range of between 5 nm and 30 nm. The light source 3 may be a plasma source, for example an LPP (laser produced plasma) source or a GDPP (gas discharge produced plasma) source. It may also be a synchrotron-based radiation source. The light source 3 may be a free electron laser (FEL).

The illumination radiation 16 emanating from the light source 3 is focused by a collector 17. The collector 17 may be a collector having one or more ellipsoidal and/or hyperboloidal reflection surfaces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 may represent a separation between a radiation source module, comprising the light source 3 and the collector 17, and the illumination optics unit 4.

The illumination optics unit 4 comprises a deflection mirror 19 and, disposed downstream thereof in the beam path, a first facet mirror 20. The deflection mirror 19 may be a plane deflection mirror or alternatively a mirror with a beam-influencing effect going beyond the pure deflection effect. In an alternative to that or in addition, the deflection mirror 19 may be in the form of a spectral filter that separates a used light wavelength of the illumination radiation 16 from extraneous light of a wavelength deviating therefrom. Should the first facet mirror 20 be arranged in a plane of the illumination optics unit 4 which is optically conjugate to the object plane 6 as a field plane, this facet mirror is also referred to as a field facet mirror. The first facet mirror 20 comprises a multiplicity of individual first facets 21, which may also be referred to as field facets. Only some of these first facets 21 are illustrated in FIG. 1 by way of example.

The first facets 21 may be embodied as macroscopic facets, for example as rectangular facets or as facets with an arcuate or an edge contour of part of a circle. The first facets 21 may take the form of plane facets or, in an alternative to that, convexly or concavely curved facets.

As is known for example from DE 10 2008 009 600 A1, the first facets 21 themselves may each also be composed of a multiplicity of individual mirrors, for example a multiplicity of micromirrors. The first facet mirror 20 may take the form of a microelectromechanical system (MEMS system) for example. For details, reference is made to DE 10 2008 009 600 A1.

The illumination radiation 16 travels horizontally, i.e. in the y-direction y, between the collector 17 and the deflection mirror 19.

In the beam path of the illumination optics unit 4, a second facet mirror 22 is disposed downstream of the first facet mirror 20. Should the second facet mirror 22 be arranged in a pupil plane of the illumination optics unit 4, this facet mirror is also referred to as a pupil facet mirror. The second facet mirror 22 may also be spaced apart from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which can for example have a round, rectangular or else hexagonal boundary, or can alternatively be facets composed of micromirrors. For details in this regard, reference is likewise made to DE 10 2008 009600 A1.

The second facets 23 may have plane or, alternatively, convexly or concavely curved reflection surfaces.

The illumination optics unit 4 thus forms a doubly faceted system. This fundamental principle is also referred to as a fly's eye integrator.

It may be advantageous to arrange the second facet mirror 22 not exactly in a plane that is optically conjugate to a pupil plane of the projection optics unit 10. For example, the second facet mirror 22 may be arranged so as to be tilted in relation to a pupil plane of the projection optics unit 10, as described for example in DE 10 2017 220 586 A1.

The second facet mirror 22 is used to image the individual first facets 21 into the object field 5. The second facet mirror 22 is the last beam-shaping mirror or else actually the last mirror for the illumination radiation 16 in the beam path upstream of the object field 5.

In a further embodiment (not illustrated) of the illumination optics unit 4, a transfer optics unit contributing for example to the imaging of the first facets 21 into the object field 5 may be arranged in the beam path between the second facet mirror 22 and the object field 5. The transfer optics unit may have exactly one mirror or alternatively two or more mirrors, which are arranged one behind another in the beam path of the illumination optics unit 4. The transfer optics unit may for example comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the first facet mirror 20 and the second facet mirror 22.

In a further embodiment of the illumination optics unit 4, the deflection mirror 19 may also be omitted, and so the illumination optics unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optics unit is often only approximate imaging.

The projection optics unit 10 comprises a plurality of mirrors Mi, which are consecutively numbered in accordance with their arrangement in the beam path of the projection exposure apparatus 1.

In the example illustrated in FIG. 1, the projection optics unit 10 comprises six mirrors M1 to M6. Alternatives with four, eight, ten, twelve or a different number of mirrors Mi are also possible. The projection optics unit 10 is a doubly obscured optics unit. The penultimate mirror M5 and the last mirror M6 each have a passage opening for the illumination radiation 16. The projection optics unit 10 has an image-side numerical aperture that is greater than 0.5 and may also be greater than 0.6 and, for example, may be 0.7 or 0.75.

Reflection surfaces of the mirrors Mi may take the form of free-form surfaces without an axis of rotational symmetry. Alternatively, the reflection surfaces of the mirrors Mi may be designed as aspherical surfaces with exactly one axis of rotational symmetry of the reflection surface shape. Just like the mirrors of the illumination optics unit 4, the mirrors Mi may have highly reflective coatings for the illumination radiation 16. These coatings may be designed as multilayer coatings, for example with alternating layers of molybdenum and silicon.

The projection optics unit 10 has a large object-image shift in the y-direction y between a y-coordinate of a center of the object field 5 and a y-coordinate of the center of the image field 11. This object-image shift in the y-direction y may be of approximately the same magnitude as a z-distance between the object plane 6 and the image plane 12.

The projection optics unit 10 may for example have an anamorphic form. It has for example different imaging scales βx, βy in the x- and y-directions x, y. The two imaging scales βx, βy of the projection optics unit 10 can be (βx, βy)=(+/−0.25, +/−0.125). A positive imaging scale β means imaging without image inversion. A negative sign for the imaging scale β means imaging with image inversion.

The projection optics unit 10 consequently leads to a reduction in size with a ratio of 4:1 in the x-direction x, i.e. in a direction perpendicular to the scanning direction.

The projection optics unit 10 leads to a reduction in size of 8:1 in the y-direction y, i.e. in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or can differ, depending on the embodiment of the projection optics unit 10. Examples of projection optics units with different numbers of such intermediate images in the x-direction x and y-direction y are known from US 2018/0074303 A1.

In each case one of the second facets 23 is assigned to exactly one of the first facets 21 for forming a respective illumination channel for illuminating the object field 5. This may for example produce illumination according to the Köhler principle. The far field is decomposed into a multiplicity of object fields 5 with the aid of the first facets 21. The first facets 21 create a plurality of images of the intermediate focus on the second facets 23 respectively assigned to them.

By way of an assigned second facet 23, the first facets 21 are each imaged onto the reticle 7 and overlaid on one another for the purpose of illuminating the object field 5. The illumination of the object field 5 is for example as homogeneous as possible. It can have a uniformity error of less than 2%. Field uniformity may be achieved by overlaying different illumination channels.

The illumination of the entrance pupil of the projection optics unit 10 may be defined geometrically by an arrangement of the second facets 23. The intensity distribution in the entrance pupil of the projection optics unit 10 can be set by selecting the illumination channels, for example the subset of the second facets 23, which guide light. This intensity distribution is also referred to as illumination setting or illumination pupil filling.

A likewise preferred pupil uniformity in the region of portions of an illumination pupil of the illumination optics unit 4 that are illuminated in a defined manner can be achieved by a redistribution of the illumination channels.

Further aspects and details of the illumination of the object field 5 and for example of the entrance pupil of the projection optics unit 10 are described below.

The projection optics unit 10 may have a homocentric entrance pupil, for example. The latter may be accessible. It may also be inaccessible.

The entrance pupil of the projection optics unit 10 regularly cannot be exactly illuminated with the second facet mirror 22. In the case of imaging by the projection optics unit 10 which telecentrically images the center of the second facet mirror 22 onto the wafer 13, the aperture rays often do not intersect at a single point. However, it is possible to find an area in which the spacing of the aperture rays that is determined in pairs becomes minimal. This area represents the entrance pupil or an area conjugate thereto in real space. For example, this area exhibits a finite curvature.

It may be the case that the projection optics unit 10 has different positions of the entrance pupil for the tangential beam path and for the sagittal beam path. In this case, an imaging element, for example an optical component part of the transfer optics unit, should be provided between the second facet mirror 22 and the reticle 7. With the aid of this optical element, the different position of the tangential entrance pupil and of the sagittal entrance pupil can be taken into account.

In the arrangement of the components of the illumination optics unit 4 illustrated in FIG. 1, the second facet mirror 22 is arranged in an area conjugate to the entrance pupil of the projection optics unit 10. The first facet mirror 20 is arranged so as to be tilted with respect to the object plane 6. The first facet mirror 20 is arranged so as to be tilted with respect to an arrangement plane defined by the deflection mirror 19. The first facet mirror 20 is arranged so as to be tilted with respect to an arrangement plane defined by the second facet mirror 22.

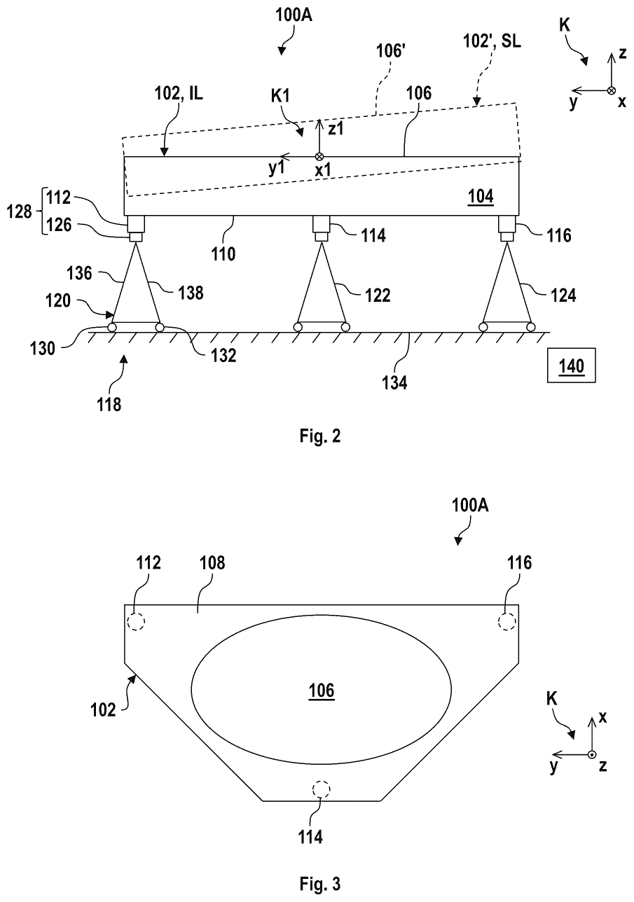

FIG. 2 shows a schematic view of one embodiment of an optical system 100A for the projection exposure apparatus 1. FIG. 3 shows a schematic plan view of the optical system 100A. Hereinafter, reference is made to FIGS. 2 and 3 concurrently.

The optical system 100A may be a projection optics unit 4 as explained above or part of such a projection optics unit 4. Therefore, the optical system 100A may also be referred to as projection optics unit. However, the optical system 100A may also be an illumination system 2 as explained above or part of such an illumination system 2.

Therefore, the optical system 100A may alternatively also be referred to as illumination system. However, it is assumed hereinafter that the optical system 100A is a projection optics unit 4 or part of such a projection optics unit 4. The optical system 100A is suitable for EUV lithography. However, the optical system 100A might also be suitable for DUV lithography.

The optical system 100A may comprise a plurality of optical elements 102, of which only one is shown in FIGS. 2 and 3 however. Therefore, only one optical element 102 is discussed below. The optical element 102 may be one of the mirrors M1 to M6. The optical element 102 comprises a substrate 104 and an optically effective surface 106, for example a mirror surface. The substrate 104 may also be referred to as mirror substrate. The substrate 104 may comprise glass, ceramic, glass ceramic or other suitable materials.

The optically effective surface 106 is provided on a front side 108 of the substrate 104. The optically effective surface 106 may be realized with the aid of a coating applied to the front side 108. The optically effective surface 106 is a mirror surface. The optically effective surface 106 is suitable for reflecting illumination radiation 16, for example EUV radiation, during operation of the optical system 100A. The optically effective surface 106 may have an oval or elliptical geometry in the plan view according to FIG. 3. The optical element 102 or the substrate 104 may have a triangular geometry. In general, however, there may be any desired geometry.

The optical element 102 has a back side 110 facing away from the optically effective surface 106 or the front side 108. The back side 110 has no defined optical properties. That is to say for example that the back side 110 is not a mirror surface and therefore does not have reflective properties either.

A plurality of mirror bushings 112, 114, 116 are provided on the back side 110. The mirror bushings 112, 114, 116 may be adhesive bushings. A first mirror bushing 112, a second mirror bushing 114 and a third mirror bushing 116 are provided. In other words, the optical element 102 comprises exactly three mirror bushings 112, 114, 116. The mirror bushings 112, 114, 116 may have geometrically identical designs. The mirror bushings 112, 114, 116 are substantially cylindrical and extend in the orientation of

FIG. 2 on the underside out of the back side 110. The mirror bushings 112, 114, 116 may be adhesively bonded to the substrate 104. The mirror bushings 112, 114, 116 form corners of an imaginary triangle.

The optical element 102 or the optically effective surface 106 has six degrees of freedom, namely three translational degrees of freedom in the first spatial direction or x-direction x, the second spatial direction or y-direction y and the third spatial direction or z-direction z, respectively, and three rotational degrees of freedom about the x-direction x, the y-direction y and the z-direction z, respectively. That is to say that a position and an orientation of the optical element 102 or of the optically effective surface 106 may be determined or described with the aid of the six degrees of freedom.

The “position” of the optical element 102 or optically effective surface 106 is for example understood to mean the coordinates thereof or the coordinates of a point of interest provided on the optical element 102 with respect to the x-direction x, the y-direction y and the z-direction z. The “orientation” of the optical element 102 or optically effective surface 106 is understood to mean for example its tilt with respect to the three directions x, y, z. That is to say, the optical element 102 or the optically effective surface 106 may be tilted about the x-direction x, the y-direction y and/or the z-direction z.

This results in the six degrees of freedom for the position and/or orientation of the optical element 102 or optically effective surface 106. A “pose” of the optical element 102 or of the optically effective surface 106 encompasses both its position and its orientation. The term “pose” is accordingly replaceable by the wording “position and orientation”, and vice versa.

FIG. 2 shows an actual pose IL of the optical element 102 or optically effective surface 106 using solid lines and a target pose SL of the optical element 102 or optically effective surface 106 using dashed lines and reference signs 102′ and 106′. The optical element 102 may be brought from its actual pose IL to the target pose SL and vice versa. For example, the optical element 102 in the target pose SL meets specific optical specifications or desired properties that the optical element 102 in the actual pose IL does not satisfy.

In order to move the optical element 102 from the actual pose IL to the target pose SL, the optical system 100A comprises an adjustment device 118. The adjustment device 118 is configured to adjust the optical element 102. In the present case, an “adjustment” or “alignment” is understood to mean for example a change in the pose of the optical element 102. For example, the optical element 102 may be moved from the actual pose IL to the target pose SL and vice versa with the aid of the adjustment device 118. The adjustment or alignment of the optical element 102 may thus be implemented with the aid of the adjustment device 118 in all six aforementioned degrees of freedom. The adjustment device 118 is what is known as a hexapod or may be referred to as such.

The adjustment device 118 comprises multiple bipods 120, 122, 124, which are shown only very schematically in FIG. 2. Each mirror bushing 112, 114, 116 is assigned one bipod 120, 122, 124. For example, this means that exactly three bipods 120, 122, 124 are provided. Each bipod 120, 122, 124 may be assigned two of the abovementioned degrees of freedom. Using the three bipods 120, 122, 124, an adjustment of the optical element 102 in all six degrees of freedom is thus possible. The bipods 120, 122, 124 are not necessarily suitable for adjusting the optical element 102. Furthermore, the bipods 120, 122, 124 might also be suitable for keeping the optical element 102 in its target pose SL, for example.

A first bipod 120 is assigned to the first mirror bushing 112. A second bipod 122 is assigned to the second mirror bushing 114. A third bipod 124 is assigned to the third mirror bushing 116. The bipods 120, 122, 124 have identical designs. Therefore, only the first bipod 120 and the first mirror bushing 112 are discussed below, which are simply referred to as bipod 120 and mirror bushing 112, respectively. All explanations given below in relation to the bipod 120 are also applicable to the bipods 122, 124, and vice versa. A corresponding statement applies to the mirror bushing 112 and the mirror bushings 114, 116.

The bipod 120 is coupled to the mirror bushing 112 via a bushing block 126. The bushing block 126 and the mirror bushing 112 form an interface 128. Such an interface 128 is assigned to each bipod 120, 122, 124. Furthermore, the bipod 120 is coupled to a load-bearing structure 134 via two joining points 130, 132. The load-bearing structure 134 can be a force frame or any other immovable structure. The load-bearing structure 134 may also be called a fixed world.

The bipod 120 comprises two manipulators 136, 138, for example a first manipulator 136 and a second manipulator 138. The six degrees of freedom of the optical element 102 can be adjusted or blocked with the aid of all the manipulators 136, 138 from all of the bipods 120, 122, 124. The manipulators 136, 138 may also be referred to as the actuating elements, actuating mechanisms or actuators. For example, the manipulators 136, 138 are what are known as voice coil manipulators (VCM) or voice coil actuators (VCA) and may be referred to as such.

Both manipulators 136, 138 are joined to the mirror bushing 112 with the aid of the bushing block 126. Furthermore, the manipulators 136, 138 are joined to the load-bearing structure 134 via the joining points 130, 132. The manipulators 136, 138 can be controlled via an open-loop and closed-loop control unit 140 of the adjustment device 118, in order to adjust the optical element 102.

All of the manipulators 136, 138 of all of the bipods 120, 122, 124 are operatively connected to the open-loop and closed-loop control unit 140, and as a result the open- loop and closed-loop control unit 140 can adjust the optical element 102 in all six degrees of freedom with the aid of a suitable control of the manipulators 136, 138. This may be implemented on the basis of sensor signals from a sensor system (not depicted), which is able to detect the actual pose IL and the target pose SL of the optical element 102.

In an installed state of the optical element 102, it is possible to calibrate a measurement point (point of interest) on the optical element 102, for example on the optically effective surface 106, with respect to a reference, a reference coordinate system K with the aforementioned directions x, y, z in the present case. For example, the point of interest may be assigned a coordinate system K1 with an x-direction x1, a y-direction y1 and a z-direction z1. In order to calibrate the optical element 102, the coordinate system K1 is aligned with the reference coordinate system K.

The calibrated optical element 102 can be removed and reinstalled or replaced with a different calibrated optical element 102. In the case of this aforementioned removal and installation or replacement of the optical element 102, the pose of the point of interest relative to the reference or the pose of the coordinate system K1 with respect to the reference coordinate system K should not change. This involves great and reproducible installation accuracy.

Suitable cylindrical fit surfaces may be provided on the mirror bushing 112 and on the bushing block 126. These cylindrical fit surfaces involve exact threading of the mirror bushing 112 and of the bushing block 126 into each other. Should the mirror bushing 112 and the bushing block 126 not be aligned exactly to each other, this may lead to the mirror bushing 112 and the bushing block 126 jamming and/or to flexures provided on the manipulators 136, 138 being subject to excessive loads. Further, an interface between the mirror bushing 112 and the bushing block 126 formed by the aforementioned fit surfaces is desirable as regards the mirror dynamics and deformations of the optically effective surface 106 (surface figure deformation, SFD).

A possibly arising reinstallation error when installing the optical element 102 is a non-systematic error as a rule. The reinstallation error may dominate the tolerance chain in the case of increasing mass and/or increasing volume of the optical element 102. Further, the complexity of the reinstallation process also increases.

Against this background, the interface 128 should be developed such that there cannot be jamming between the bushing block 126 and the mirror bushing 112. Furthermore, manual manipulation of elements of the bipod 120 should be rendered dispensable. Unacceptable effects, for example in respect of the dynamics, should no longer occur.

Thus, the interface 128 should be resistant to jamming and be self-centering, highly accurate and very stiff.

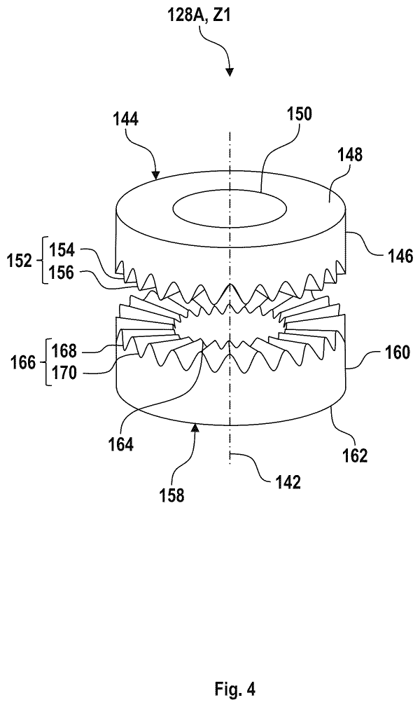

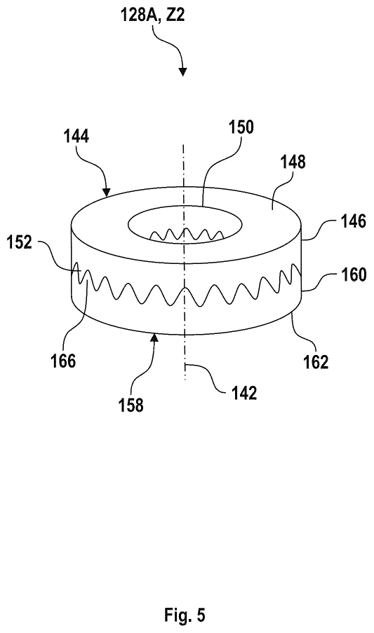

FIG. 4 shows a schematic perspective view of an embodiment of an interface 128A as mentioned previously. FIG. 5 shows a further schematic perspective view of the interface 128A. Hereinbelow, FIGS. 4 and 5 are referred to jointly.

The interface 128A may be assigned a center axis or axis of symmetry 142, in relation to which the interface 128A is constructed in rotationally symmetric fashion. The axis of symmetry 142 is oriented parallel to the z-direction z or coincides with the latter. The interface 128A comprises a first serration portion 144, which is assigned to the mirror bushing 112. The first serration portion 144 and the mirror bushing 112 may be two mutually separate components that are connected to each other. However, the first serration portion 144 may also be formed in one piece, especially from one piece of material, with the mirror bushing 112.

In this case, “in one piece” or “integrally” means that the first serration portion 144 and the mirror bushing 112 form a joint component and are not assembled from different component parts. “From one piece of material” means that the serration portion 144 and the mirror bushing 112 are produced from the same material throughout, for example a metallic material.

The first serration portion 144 may be constructed in rotationally symmetric fashion in relation to the axis of symmetry 142. The first serration portion 144 is cylindrical and comprises a cylindrical outer surface 146 and an end face 148 which may face the back side 110. The end face 148 is oriented perpendicular to the axis of symmetry 142. In the center, the first serration portion 144 is perforated by a circular aperture 150.

Facing away from the end face 148, the first serration portion 144 comprises what is known as a first Hirth serration 152. In the present case, a “Hirth serration” is understood to mean, for example, an axially effective, plane-side serration. The first Hirth serration 152 comprises a multiplicity of teeth 154, 156, only two of which have been provided with a reference sign in FIG. 4. The teeth 154, 156 are arranged with a uniform distribution about the axis of symmetry 142 and, starting from the aperture 150, extend radially outward to the outer surface 146. The first Hirth serration 152 forms a complete annulus that extends around the axis of symmetry 142. However, this is not mandatory.

In addition to the first serration portion 144, the interface 128A comprises a second serration portion 158. The second serration portion 158 and the first serration portion 144 may be constructed in an identical, albeit mirror-inverted fashion. The second serration portion 158 is assigned to the bushing block 126. The second serration portion 158 and the bushing block 126 may be two mutually separate components that are connected to each other. However, the second serration portion 158 may also be formed in one piece, especially from one piece of material, with the bushing block 126.

The second serration portion 158 may also be constructed in rotationally symmetric fashion in relation to the axis of symmetry 142. The second serration portion 158 is cylindrical and comprises a cylindrical outer surface 160 and an end face 162 which may face away from the back side 110. The end face 162 is oriented perpendicular to the axis of symmetry 142. In the center, the second serration portion 158 is perforated by a circular aperture 164.

Facing away from the end face 162 and facing the first Hirth serration 152, the second serration portion 158 comprises a second Hirth serration 166. The second Hirth serration 166 comprises a multiplicity of teeth 168, 170, only two of which have been provided with a reference sign in FIG. 4. The teeth 168, 170 are arranged with a uniform distribution about the axis of symmetry 142 and, starting from the aperture 164, extend radially outward to the outer surface 160. The second Hirth serration 166 forms a complete annulus that extends around the axis of symmetry 142. However, this is not mandatory.

For greatest resistance to wear, the Hirth serrations 152, 166 may be martensite hardened. It is possible to have a surface coating, for example a DLC (diamond like carbon) coating or the like. This may reduce wear.

To connect the serration portions 144, 158 to each other, their Hirth serrations 152, 166 engage interlockingly in one another. An interlocking connection arises as a result of two connection partners, the Hirth serrations 152, 166 in the present case, meshing with or engaging behind one another. Interlocking connections can be released and reestablished as often as desired.

As a result of the engagement of the Hirth serrations 152, 166, the interface 128A can be brought from a first state Z1, shown in FIG. 4, in which the Hirth serrations 152, 166 are not in interlocking engagement, into a second state Z2, shown in FIG. 5, in which the Hirth serrations 152, 166 are in interlocking engagement. To this end, the serration portions 144, 158 are moved toward each other along the axis of symmetry 142 such that the Hirth serrations 152, 166 engage with each other. In the present case, the Hirth serrations 152, 166 “not being in engagement” in the first state Z1 means that, for example, the Hirth serrations 152, 166 do not interlockingly engage with each other in the first state Z1.

As a result of using the Hirth serrations 152, 166, it is possible to position or secure the pose of the optical element 102 in all six degrees of freedom. A high reproducibility accuracy of better than 5 μm can be achievable. Despite a relatively large number of effective surfaces, this may be achieved by the principle of elastic averaging. Further, frictional effects may also be reduced. There are no force-dependent stiffnesses. Since the interface 128A is self-centering, a lower accuracy of the interface 128A itself is involved. The interface 128A allows the transfer of large forces and torques.

The aforementioned principle of “elastic averaging” describes a state in which two objects, the serration portions 144, 158 in the present case, are connected to one another in a very overdetermined manner by way of many contact points. The high degree of static overdetermination involves very accurate surfaces and tolerances. However, as soon as this is achieved, this leads to a further improvement in the overall accuracy as a result of the averaging of inaccuracies. In this case, the manufacturing accuracy of the machines used in production may frequently be surpassed. Moreover, the stiffness and load-bearing capacity multiply with increasing degree of static overdetermination.

The interface 128A allows a high accuracy in repetition and reproducibility. This is virtually independent of a radius of the respective Hirth serration 152, 166. A high level of stiffness and a self-centering effect of the interface 128A are achieved. The interface 128A is insensitive to tilts of the serration portions 144, 158 relative to one another.

To install the serration portions 144, 158, all that is involved is a movement in one direction, specifically along the axis of symmetry 142 or in the z-direction z. This yields a capture range in the order of a few millimeters. The interface 128A has its thermal center on the axis of symmetry 142. On account of a broad contact surface of the Hirth serrations 152, 166, this results in a high resistance to wear.

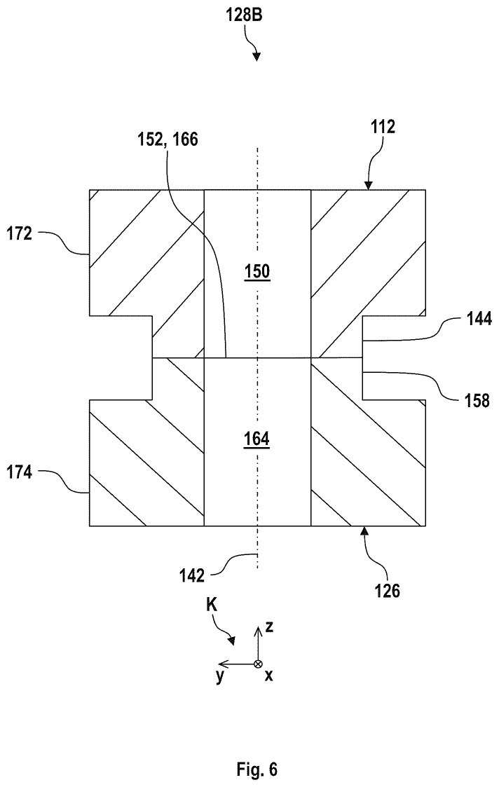

FIG. 6 shows a schematic sectional view of a further embodiment of an interface 128B as explained above.

The explanations given below in relation to the interface 128B are correspondingly applicable to the interface 128A. The mirror bushing 112 and the bushing block 126 may be part of the interface 128B. As evident from FIG. 6, the first serration portion 144 is formed in one piece, especially from one piece of material, with the mirror bushing 112 in this embodiment of the interface 128B. That is to say the mirror bushing 112 and the first serration portion 144 form a joint component.

For example, the mirror bushing 112 comprises a base portion 172, from which the first serration portion 144 extends outward on the underside in the orientation of FIG. 6. The aperture 150 may pass through the entire mirror bushing 112. However, this is not mandatory. The mirror bushing 112 may also be rotationally symmetrical in relation to the axis of symmetry 142. This is not mandatory either.

The second serration portion 158 is formed in one piece, especially from one piece of material, with the bushing block 126. That is to say the bushing block 126 and the second serration portion 158 form a joint component. For example, the bushing block 126 comprises a base portion 174, from which the second serration portion 158 extends outward on the top side in the orientation of FIG. 6. The aperture 164 may pass through the entire bushing block 126. However, this is not mandatory. The bushing block 126 may be rotationally symmetrical in relation to the axis of symmetry 142. This is not mandatory either.

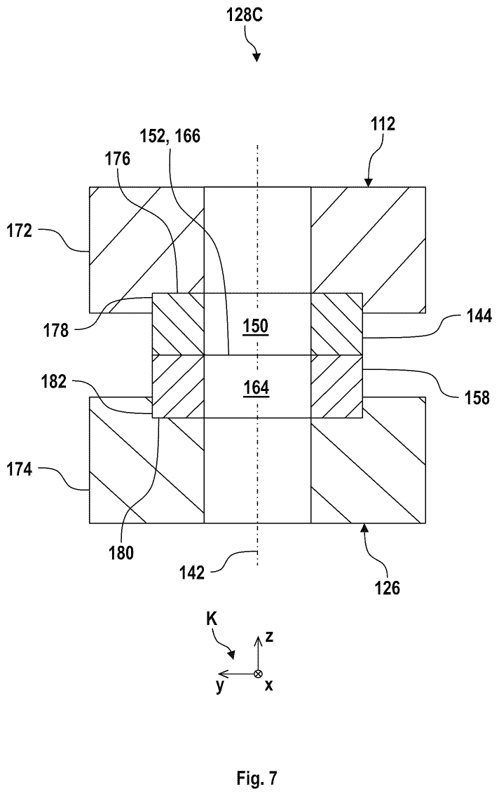

FIG. 7 shows a schematic sectional view of a further embodiment of an interface 128C as explained above.

The explanations given below in relation to the interface 128C are correspondingly applicable to the interface 128A. In contrast to the interface 128B, the mirror bushing 112 and the first serration portion 144 of the interface 128C are two mutually separated components that are connected, for example screwed, to each other. A corresponding statement applies to the bushing block 126 and the second serration portion 158, which are also two mutually separated components.

The mirror bushing 112 comprises a base portion 172 with a contact surface 176, against which the end face 148 of the first serration portion 144 rests, and a cylindrical fit surface 178, against which the outer surface 146 of the first serration portion 144 is guided. Accordingly, the bushing block 126 comprises a base portion 174 with a contact surface 180, against which the end face 162 of the second serration portion 158 rests, and a cylindrical fit surface 182, against which the outer surface 160 of the second serration portion 158 is guided.

The embodiments of the interface 128B, 128C are also combinable in such a way that, for example, the mirror bushing 112 and the first serration portion 144 are connected to one another in one piece, especially in one piece of material, and the bushing block 126 and the second serration portion 158 are two mutually separated components. A corresponding statement applies vice versa.

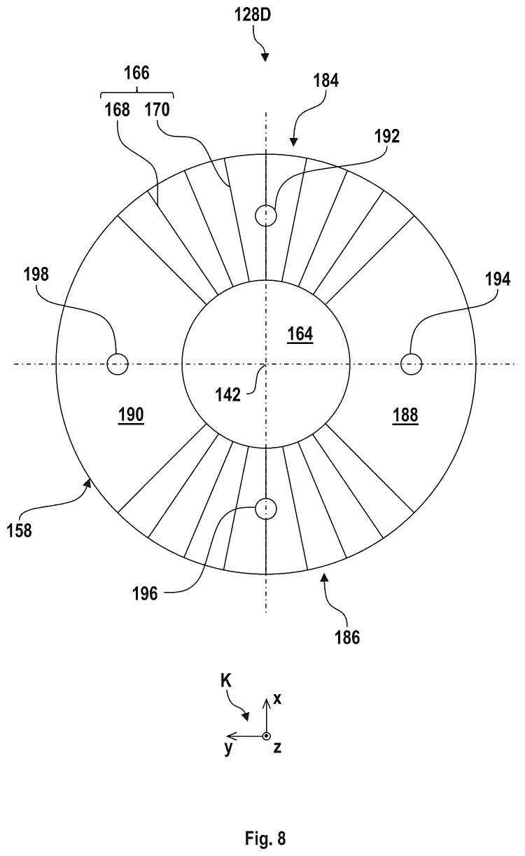

FIG. 8 shows a schematic plan view of a further embodiment of an interface 128D as explained above.

The explanations below relating to the interface 128D are correspondingly applicable to the various embodiments of the interface 128A, 128B, 128C as explained above. For example, FIG. 8 only shows the second serration portion 158 of the interface 128D. The statements given below in relation to the second serration portion 158 are correspondingly applicable to the first serration portion 144.

The second serration portion 158 comprises a second Hirth serration 166, as mentioned above, with any desired number of teeth 168, 170. In contrast to the interface 128A, the second Hirth serration 166 of the interface 128D is not continuous but segmented. Accordingly, the second Hirth serration 166 may be referred to as segmented or non-continuous Hirth serration.

In view of the second Hirth serration 166, “segmented” means that, for example, a plurality of serration segments 184, 186 with teeth 168, 170 are provided and arranged in alternation with toothless or tooth-free segments 188, 190. Thus, a respective toothless segment 188, 190 is placed between two serration segments 184, 186, and vice versa. By contrast, “continuous” means that the second Hirth serration 166 extends around the axis of symmetry 142 in full. The toothless segments 188, 190 may also be referred to as segments without teeth or segments free from teeth.

There can be any desired number of serration segments 184, 186. For example, at least two serration segments 184, 186 and at least two toothless segments 188, 190 are provided. Each serration segment 184, 186 can comprise at least four teeth 168, 170. The toothless segments 188, 190 may be provided for manufacturing reasons.

In the case that the second serration portion 158 and the bushing block 126 are two mutually separated components, the second serration portion 158 may comprise a plurality of fastening apertures 192, 194, 196, 198 through which fastening elements, for example screws, can be guided in order to securely connect the second serration portion 158 to the bushing block 126. There can be any desired number of fastening apertures 192, 194, 196, 198. For example, the fastening apertures 192, 194, 196, 198 are arranged distributed around the axis of symmetry 142 with uniform spacing from one another. The same applies to the first serration portion 144.

Such fastening apertures 192, 194, 196, 198 may also be provided in the interfaces 128A, 128C as explained above. It is possible to omit the fastening apertures 192, 194, 196, 198 in the case of the interface 128B in accordance with FIG. 6 since the first serration portion 144 is formed in one piece with the mirror bushing 112 and the second serration portion 158 is formed in one piece with the bushing block 126.

Returning now to FIG. 8, the fastening apertures 192, 194, 196, 198 may be provided both in the serration segments 184, 186 and in the toothless segments 188, 190. In the region of the serration segments 184, 186, the fastening apertures 192, 194, 196, 198 are guided directly through the second Hirth serration 166.

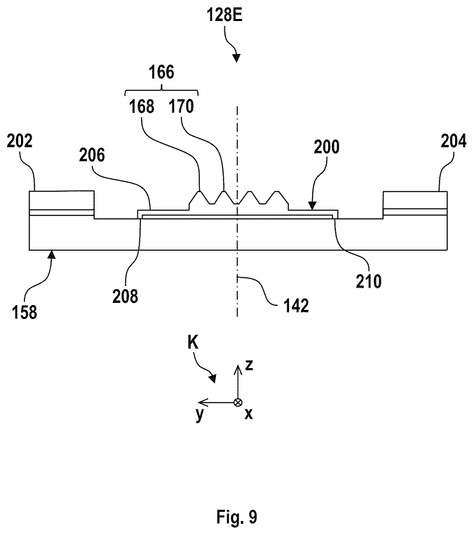

FIG. 9 shows a schematic side view of a further embodiment of an interface 128E as explained above.

The explanations below relating to the interface 128E are correspondingly applicable to the various embodiments of the interface 128A, 128B, 128C, 128D as explained above. For example, FIG. 9 only shows the second serration portion 158 of the interface 128E. The statements given below in relation to the second serration portion 158 are correspondingly applicable to the first serration portion 144.

This embodiment of the interface 128E provides for a segmented second Hirth serration 166 as explained in relation to FIG. 8. For example, four serration segments 200, 202, 204 are provided, between which toothless segments 188, 190 (FIG. 8) as explained above are provided. Only the serration segment 200 is discussed below. All explanations in relation to the serration segment 200 are applicable to the serration segments 202, 204.

The serration segment 200 can comprise at least four teeth 168, 170, which are arranged on a spring element 206. The spring element 206 is a leaf spring element. The spring element 206 is located in a plane spanned by the x-direction x and the y-direction y. That is to say the spring element 206 is oriented perpendicular to the z-direction z. The spring element 206 is joined to the second serration portion 158 via two connection elements 208, 210. The second Hirth serration 166, the spring element 206 and the connection elements 208, 210 are formed in one piece, especially from one piece of material, with the second serration portion 158.

The spring element 206 is resiliently deformable and ensures a very low stiffness of the interface 128E when considered in the z-direction z. By way of the interface 128E, it is possible to block the translational degrees of freedom in the x-direction x and the y-direction y and block the rotational degree of freedom about the z-direction z. Positioning in the z-direction z can be implemented by virtue of the mirror bushing 112 resting against the bushing block 126.

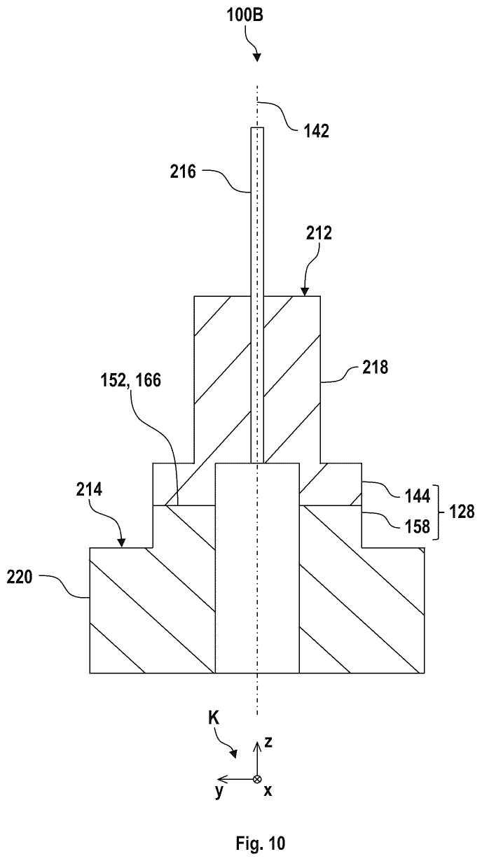

FIG. 10 shows a schematic sectional view of a further embodiment of an optical system 100B.

The embodiments of the interface 128A, 128B, 128C, 128D, 128E, as explained above, can be used both in conjunction with the optical system 100A and in conjunction with the optical system 100B. The optical system 100B comprises an optical element 212 and a load-bearing structure 214. The optical element 212 comprises a first serration portion 144, as explained above, with a first Hirth serration 152. The load-bearing structure 214 comprises a second serration portion 158 with a second Hirth serration 166. In order to align the optical element 212 and the load-bearing structure 214, the Hirth serrations 152, 166 interlockingly engage with one another.

The optical element 212 comprises an optical waveguide 216 and a fiber connector 218, which carries the optical waveguide 216. The first serration portion 144 is provided on the fiber connector 218. The fiber connector 218 and the first serration portion 144 may be connected to one another in one piece, especially in one piece of material, or form two mutually separated components.

The load-bearing structure 214 may be an interferometer or the like. The load-bearing structure 214 may be a housing or the like. The load-bearing structure 214 may comprise a base portion 220, on which the second serration portion 158 is provided. The base portion 220 and the second serration portion 158 may be connected to one another in one piece, especially in one piece of material, or form two mutually separated components.

A replacement of the optical element 212 or of the optical waveguide 216 may become desirable, for example due to damage to the optical waveguide 216. The exact alignment of the optical waveguide 216 usually involves a great amount of time. With the aid of the embodiments of the interface 128A, 128B, 128C, 128D, 128E as explained above, it is possible to reproducibly align the optical element 212 or the optical waveguide 216 with great accuracy.

Although the present disclosure has been described on the basis of exemplary embodiments, it is modifiable in diverse ways.

### LIST OF REFERENCE SIGNS

1 Projection exposure apparatus
2 Illumination system
3 Light source
4 Illumination optics unit
5 Object field
6 Object plane
7 Reticle
8 Reticle holder
9 Reticle displacement drive
10 Projection optics unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100A Optical system
100B Optical system
102 Optical element
102′ Optical element
104 Substrate
106 Optically effective surface
106′ Optically effective surface
108 Front side
110 Back side
112 Mirror bushing
114 Mirror bushing
116 Mirror bushing
118 Adjustment device
120 Bipod
122 Bipod
124 Bipod
126 Bushing block
128 Interface
128A Interface
128B Interface
128C Interface
128D Interface
128E Interface
130 Joining point
132 Joining point
134 Load-bearing structure
136 Manipulator
138 Manipulator
140 Open-loop and closed-loop control unit
142 Axis of symmetry
144 Serration portion
146 Outer surface
148 End face
150 Aperture
152 Hirth serration
154 Tooth
156 Tooth
158 Serration portion
160 Outer surface
162 End face
164 Aperture
166 Hirth serration
168 Tooth
170 Tooth
172 Base portion
174 Base portion
176 Contact surface
178 Fit surface
180 Contact surface
182 Fit surface
184 Serration segment
186 Serration segment
188 Segment
190 Segment
192 Fastening aperture
194 Fastening aperture
196 Fastening aperture
198 Fastening aperture
200 Serration segment
202 Serration segment
204 Serration segment
206 Spring element
208 Connection element
210 Connection element
212 Optical element
214 Load-bearing structure
216 Optical waveguide
218 Fiber connector
220 Base portion
IL Actual pose
K Reference coordinate system
K1 Coordinate system
M1 Mirror
M2 Mirror
M3 Mirror
M4 Mirror
M5 Mirror
M6 Mirror
SL Target pose
X x-direction
x1 x-direction
y y-direction
y1 y-direction
Z z-direction
z1 z-direction
Z1 State
Z2 State

What is claimed is:

1. An optical system, comprising
a mirror;
a load-bearing structure; and
an interface coupling the mirror and the load-bearing structure,
wherein:
the interface comprises a first Hirth serration which is assigned to the mirror;
the interface comprises a second Hirth serration which is assigned to the load-bearing structure; and
the first and second Hirth serrations mesh to define a pose of the mirror in a reference coordinate system.

2. The optical system of claim 1, wherein:
the interface comprises a first serration portion which comprises the first Hirth serration;
the interface comprises a second serration portion comprising the second Hirth serration;
the first serration portion of the interface is connected to the mirror; and
the second serration portion of the interface is connected to the load-bearing structure.

3. The optical system of claim 2, wherein at least one of the following holds:
the first serration portion comprises first fastening apertures fastening the first serration portion, the first fastening apertures extending through the first serration portion; and
the second serration portion fastening apertures fastening second serration portion, the second fastening apertures extending through the second serration portion.

4. The optical system of claim 2, wherein at least one of the following holds:
the first serration portion comprises a first central aperture around which the first Hirth serration extends; and
the second serration portion comprises a second central aperture around which the second Hirth serration extends.

5. The optical system of claim 2, wherein at least one of the following holds:
the first Hirth serration comprises first serration segments alternating with first toothless segments; and
the second Hirth serration comprises second serration segments alternating with second toothless segments.

6. The optical system of claim 2, wherein at least one of the following holds:
the first serration portion comprises a first spring element carrying a first plurality of teeth; and
the second serration portion comprises a second spring element carrying a second plurality of teeth.

7. The optical system of claim 2, wherein at least one of the following holds:
the first serration portion comprises a first spring element carrying a first plurality of teeth, and the first spring element extends perpendicular to an axis of symmetry of the interface; and
the second serration portion comprises a second spring element carrying a second plurality of teeth, and the second spring element extends perpendicular to an axis of symmetry of the interface.

8. The optical system of claim 2, wherein at least one of the following holds:
the first serration portion comprises a first spring element carrying a first plurality of teeth, the first spring element extends perpendicular to an axis of symmetry of the interface, and the first spring element has its lowest stiffness along the axis of symmetry of the interface; and
the second serration portion comprises a second spring element carrying a second plurality of teeth, the second spring element extends perpendicular to an axis of symmetry of the interface and the second spring element has its lowest stiffness along the axis of symmetry of the interface.

9. The optical system of claim 2, wherein:
the interface comprises a first mirror bushing and a bushing block;
the first mirror bushing is assigned to the mirror;
the first mirror bushing comprises the first serration portion;
the bushing block is assigned to the load-bearing structure; and
the bushing block comprises the second serration portion.

10. The optical system of claim 9, wherein the mirror comprises an optically effective surface and a back side facing away from the optically effective surface, and wherein the mirror bushing is connected to the back side of the mirror.

11. The optical system of claim 9, wherein at least one of the following holds:
the mirror bushing and the first serration portion define one piece of material; and
the bushing block and second serration portion define one piece of material.

12. The optical system of claim 9, wherein at least one of the following holds:
the mirror bushing and the first serration portion define multiple pieces; and
the bushing block and second serration portion define multiple pieces.

13. The optical system of claim 9, further comprising second and third mirror bushings connected to the mirror, wherein each of the first, second and third mirror bushings is assigned two degrees of freedom of the mirror.

14. The optical system of claim 13, further comprising first, second and third bipods coupling the mirror to the load-bearing structure via the bushing block, wherein each of the first, second and third mirror bushings is assigned to a corresponding one of the first, second and third bipods.

15. The optical system of claim 2, wherein:
the first serration portion comprises first fastening apertures fastening the first serration portion, the first fastening apertures extending through the first serration portion; and
the second serration portion fastening apertures fastening second serration portion, the second fastening apertures extending through the second serration portion.

16. The optical system of claim 15, wherein:
the first serration portion comprises a first central aperture around which the first Hirth serration extends; and
the second serration portion comprises a second central aperture around which the second Hirth serration extends.

17. The optical system of claim 16, wherein:
the first Hirth serration comprises first serration segments alternating with first toothless segments; and
the second Hirth serration comprises second serration segments alternating with second toothless segments.

18. The optical system of claim 17, wherein:
the first serration portion comprises a first spring element carrying a first plurality of teeth; and
the second serration portion comprises a second spring element carrying a second plurality of teeth.

19. The optical system of claim 1, wherein the mirror comprises an optical waveguide and a fiber connector carrying the optical waveguide, wherein the first Hirth serration is on the fiber connector.

20. An apparatus, comprising:
an optical system according to claim 1,
wherein the apparatus is a projection exposure apparatus.
